(19) United States
(12) Patent Application Publication
(10) Pub. No.: US 2026/0113873 A1
(43) Pub. Date: Apr. 23, 2026

(54) COOLING DISTRIBUTION UNIT WITH CASTERS, LEVELING FEET, AND SLIDING PUMP PLATES

(71) Applicant: LTI Holdings, Inc., Pleasanton, CA (US)

(72) Inventors: Steven J. Medeiros, Loudon, NH (US); Tristan G. Whiting, Watertown, MA (US)

(21) Appl. No.: 19/359,900

(22) Filed: Oct. 16, 2025

Related U.S. Application Data
(60) Provisional application No. 63/708,555, filed on Oct. 17, 2024.

(51) Int. Cl. H05K 7/20

(52) U.S. Cl. CPC H05K 7/20272; H05K 7/20263

(57) ABSTRACT

A cooling distribution unit includes a primary closed loop configured to circulate a first fluid, a secondary closed loop configured to circulate a second fluid, a heat exchanger configured to exchange heat between the second fluid and the first fluid, a first pump and a second pump positioned along parallel lines within the closed loop, a housing defining an interior compartment within which the heat exchanger, the first pump, and the second pump are housed. The housing includes a frame having a top side, a bottom side positioned opposite the top side, and a plurality of corner segments extending between the top side and the bottom side. The bottom side includes a plurality of casters configured to support a weight of the cooling distribution unit, and wherein the bottom side further includes a plurality of leveling feet.

### CROSS-REFERENCE TO RELATED APPLICATIONS

This application claims priority to U.S. Provisional Application No. 63/708,555, filed October 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU’s) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a primary closed loop configured to circulate a first fluid, a secondary closed loop configured to circulate a second fluid across one or more electrical components to pick up heat from the electrical components, a heat exchanger configured to exchange heat between the second fluid and the first fluid such that a portion of the heat picked up from the electrical components is transferred from the second fluid to the first fluid, a first pump and a second pump positioned along parallel lines within the closed loop, a housing defining an interior compartment within which the heat exchanger, the first pump, and the second pump are housed. The housing includes a frame having a top side, a bottom side positioned opposite the top side, and a plurality of corner segments extending between the top side and the bottom side. The bottom side includes a plurality of casters configured to support a weight of the cooling distribution unit, and the bottom side further includes a plurality of leveling feet.

In accordance with another example, a cooling distribution unit includes a primary closed loop configured to circulate a first fluid, and a secondary closed loop configured to circulate a second fluid across one or more electrical components to pick up heat from the electrical components. The cooling distribution unit further includes a heat exchanger configured to exchange heat between the second fluid and the first fluid such that a portion of the heat picked up from the electrical components is transferred from the second fluid to the first fluid. The cooling distribution unit further includes a first pump, a second pump, and a housing defining an interior compartment within which the heat exchanger, the first pump, and the second pump are housed. The first pump is arranged on a first slide plate and the second pump is arranged on a second slide plate.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a partial, close-up perspective view of a bottom side of the cooling distribution unit of FIG. 1.

FIG. 6 is a partial, close-up perspective view of an interior compartment of the cooling distribution unit of FIG. 1.

### DETAILED DESCRIPTION

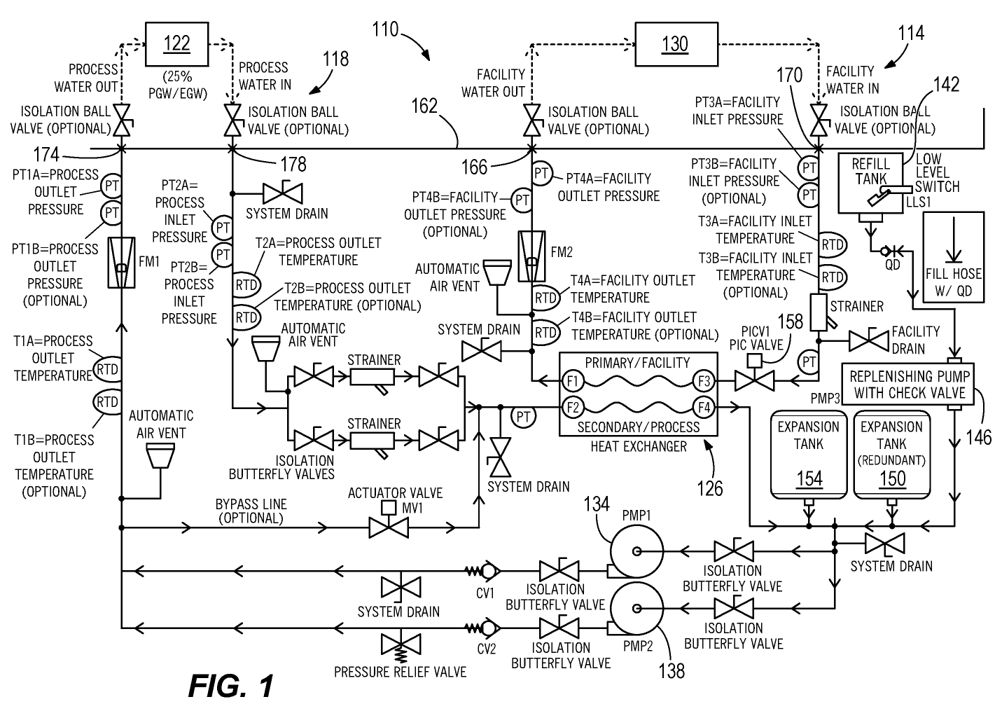

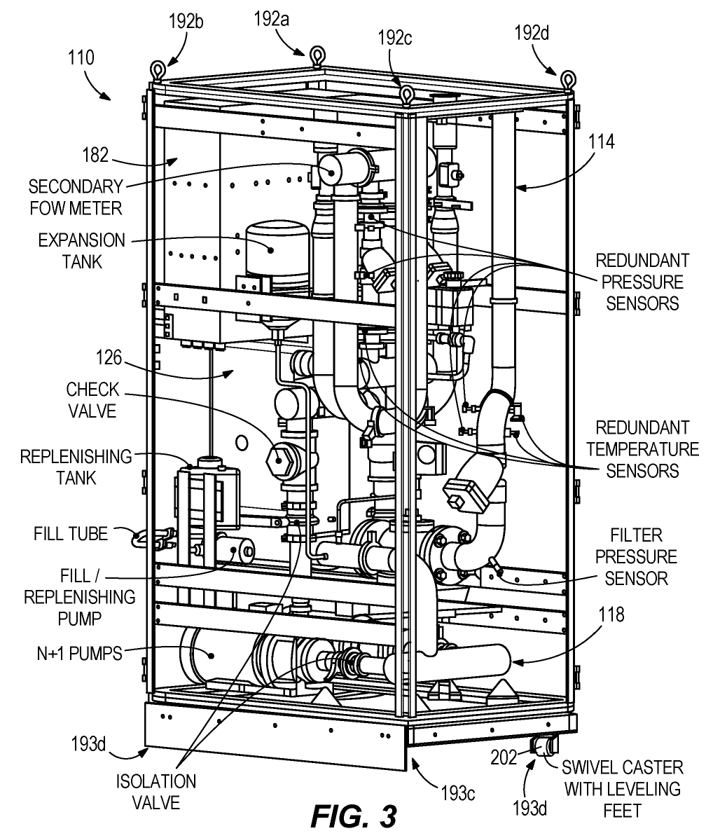

FIGS. 1-6 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

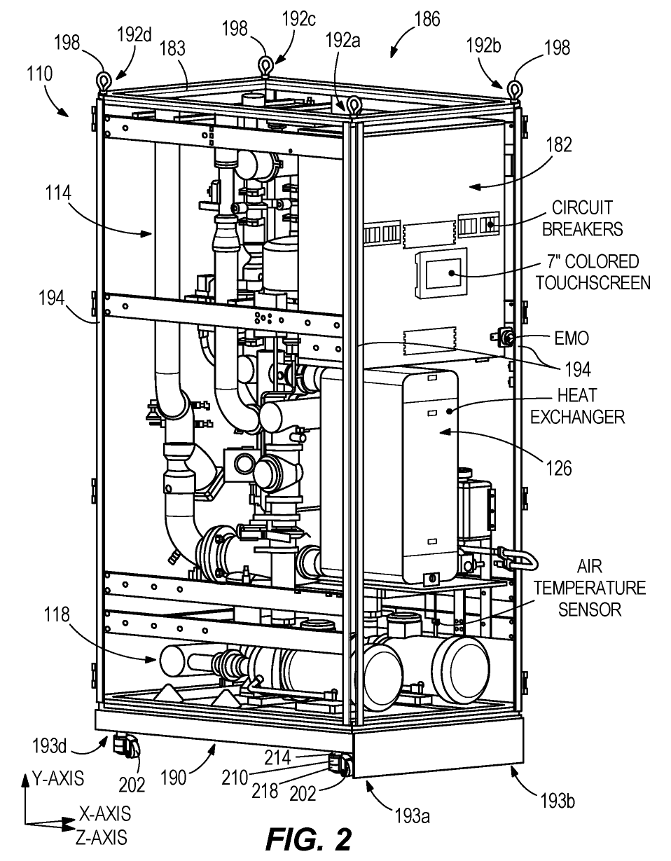

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/ or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50GPM, 100GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. The housing 162 defines an interior compartment 164 within which various components of the cooling distribution unit 110 are housed. In some examples, the housing 162 may include one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, where the primary closed loop 114 enters, and where the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 2-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

As best shown in FIG. 2, the cooling distribution unit 110 is described herein relative to a coordinate system such that the cooling distribution unit 110 has a length defined along an X-axis, has a width defined along a Z-axis, and has a height defined along a Y-axis (e.g., vertical axis). As described below, the cooling distribution unit 110 extends along or is oriented relative to the coordinate system. It will be appreciated that, as viewed in the Figures, the X-axis defines a lateral direction associated with the cooling distribution unit 110 (e.g., defining a left side of the cooling distribution unit 110 and a right side of the cooling distribution unit 110, respectively, when viewed from a front of the cooling distribution unit 110), the Y-axis defines an upward direction and a downward direction associated with the cooling distribution unit 110 (e.g., defining a top or upper side of the cooling distribution unit 110 and a bottom or lower side of the cooling distribution unit 110, respectively, when viewed from the front of the cooling distribution unit 110), and the Z-axis defines a forward direction and a rearward direction (e.g., defining a front side of the cooling distribution unit 110 and a rear side of the cooling distribution unit 110, respectively).

With reference to FIGS. 2-4, in the illustrated example, the cooling distribution unit 110 further includes a frame 183 forming part of the overall housing 162. The frame 183 includes a first or top side 186 and a second or bottom side 190. In the illustrated example, the top side 186 and the bottom side 190 are substantially rectangular in shape. Accordingly, the top side 186 includes four corners 192a-d. Similarly, the bottom side 190 includes four corners which correspond with and align with the corners of the top side 186. The frame 183 further includes a plurality of corner segments 194 extending along the Y-axis and joining the top side 186 and the bottom side 190. In the illustrated example, the frame 183 includes four (4) corner segments 194a-d which correspond with each corner of the top side 186 and the bottom side 190, respectively.

In the illustrated example, the top side 186 includes a plurality of eyelet hooks 198 configured to allow a user to secure the cooling distribution unit 110 and prevent unwanted movement. The top side 186 includes four (4) eyelet hooks 198 which correspond with each corner 192a-d of the top side 186. Other examples include other numbers and/or positions of eyelet hooks, or include no eyelet hooks.

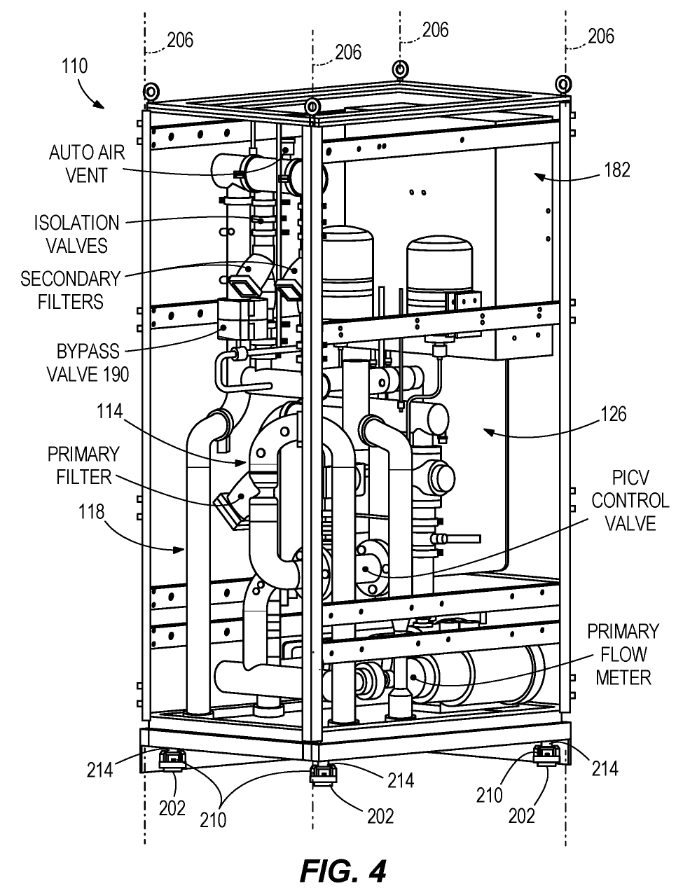

The bottom side 190 includes a plurality of casters 202 which correspond for example with each corner 193a-d of the bottom side 190. Accordingly, the bottom side 190 includes four (4) casters 202. Other examples include other numbers and arrangements of casters, or include no casters. The casters 202 are configured to support the weight of the cooling distribution unit 110 and allow a user to easily move or reposition the cooling distribution unit 110. In the illustrated example, the plurality of casters 202 are configured to support up to 1500 pounds. In other examples, the plurality of casters 202 may support any weight between 1000 pounds and 2000 pounds, or other values and ranges of values. In some examples, the casters 202 are rotatable about a plurality of parallel axes such as axes 206 (FIG. 4) or other axes which extend parallel to the Y-axis. In some examples, each of the plurality of axes 206 corresponds with and axially extends through each corner segment 194. In other examples the casters 202 are rotatable about axes that do not extend through each corner segment 194.

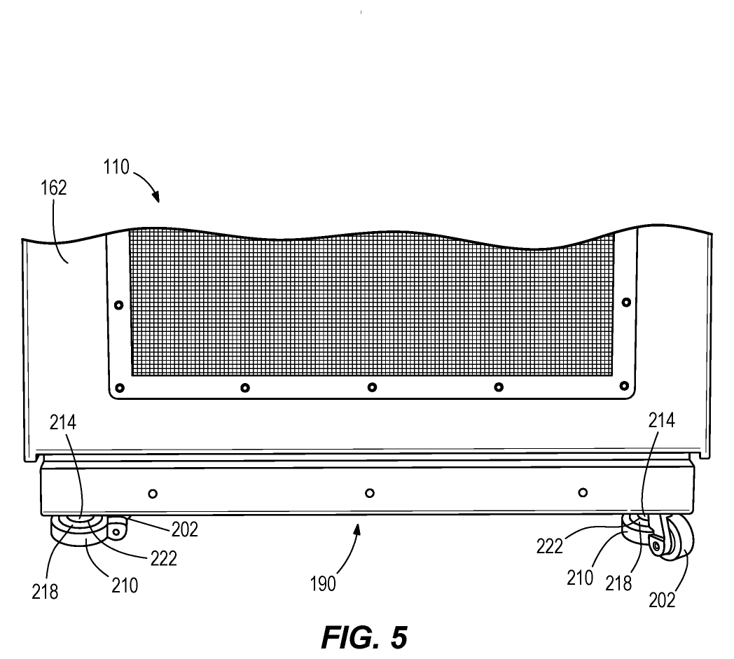

To prevent unwanted rolling, in some examples the bottom side 190 may additionally or alternatively include a plurality of leveling feet 210 (e.g., adjacent to each of the plurality of casters 202, integrated with the plurality of casters, and/or separately spaced from the plurality of casters 202). FIGS. 4 and 5 illustrate examples of leveling feet 210. In some examples, similar to the plurality of casters 202 described above, the plurality of leveling feet 210 correspond with each corner 193a-d of the bottom side 190. In some examples, the plurality of leveling feet 210 may be attached to the plurality of casters 202 (but movable relative thereto), or may be separate from the casters 202.

With reference to FIGS. 4 and 5, in some examples the plurality of leveling feet 210 each include a screw portion 214 and a plate 218. The plate 218 (or a portion thereof) may be configured to rotate about the screw portion 214 (and for example an axis located on or parallel to one of the axes 206). The plate 218 may include a threaded aperture 222 (FIG. 5), for example, configured for receiving the screw portion 214. When the plate 218 is rotated (e.g., in a clockwise direction), the plate 218 is configured to move up the screw portion 214, thereby shortening the leveling foot 210. In contrast, when the plate 218 is rotated in a different (e.g., counterclockwise) direction, the plate 218 is configured to move down the screw portion 214, thereby extending the leveling foot 210. FIG. 2 further illustrates a leveling foot 210 with a plate 218 and a screw portion 214. Other examples include other types of leveling feet 210, including leveling feet 210 having portions that pivot and/or rotate vertically downwardly or upwardly, and/or rotate outwardly, forming feet to stabilize the cooling distribution unit 110 and inhibit or prevent the cooling distribution unit 110 from moving (e.g., along the X axis or the Y axis).

In operation, in response to a user rolling the cooling distribution unit 110 to an appropriate or desired position, the user may extend the leveling feet 210 until the leveling feet 210 fully support the cooling distribution unit 110 (e.g., in place of the plurality of casters 202). To do so, in some examples a user may extend each of the plurality of leveling feet 210 individually in increments of two complete revolutions about the screw portion 214 (or otherwise extend and/or lower and extend the leveling feet 210) until the leveling feet 210 are appropriately extended. Accordingly, when the leveling feet 210 fully support the cooling distribution unit 110, the casters 202 are no longer in contact with the ground. In other words, once the cooling distribution unit 110 is raised onto the leveling feet 210, an air gap may be disposed between the floor and a bottom of the casters 202. In some examples, the air gap may be measured to have a minimum height of 1/8 inches (3 millimeters) and a maximum height of ½ inches (13 millimeters). Other examples include different values or ranges of values for an air gap or minimum and maximum heights. In some examples, no air gap is provided.

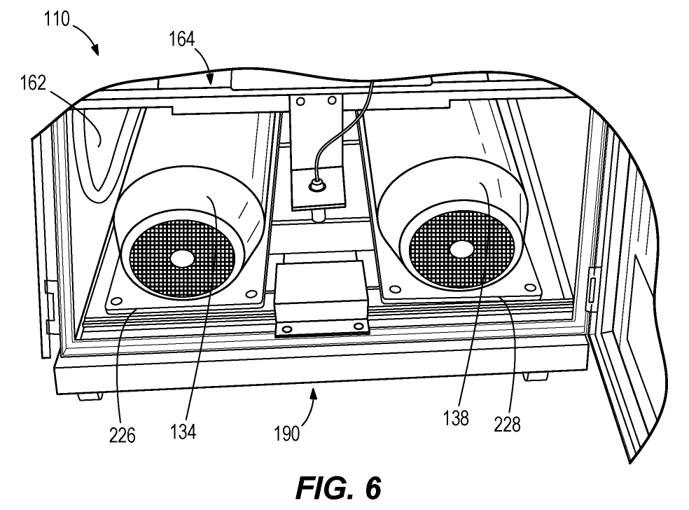

With reference to FIG. 6, the first pump 134 may be arranged on a first slide plate 226, and the second pump 138 may be arranged on a second slide plate 228, respectively, to easily attach and remove the first pump 134 and the second pump 138 from the cooling distribution unit 110 for replacement. The first slide plate 226 and the second slide plate 228 may also be referred to collectively as, slide plates 226, 228. The slide plates 226, 228 may be arranged, for example, on rails within the interior compartment 164 and may be attached for example to an interior portion of the bottom side 190. The rails may be configured to support the slide plates 226, 228 and allow for relative sliding of the slide plates 226, 228 in and out of the cooling distribution unit 110 (e.g., along a direction parallel to the X axis or the Y axis.

The second pump 138 may be a redundant pump. In other words, the second pump 138 may be configured to automatically turn on only in response to failure of the first pump 134, or may work together with the first pump 134 during use. Accordingly, a user may change a failed pump while the unit is still running. As such, the slide plates 226, 228 may allow the user to change or remove the failed pump without requiring the user to disassemble the cooling distribution unit 110.

In the illustrated example, the cooling distribution unit 110 has an overall dimension of 31.5” by 47.4” by 84.5”, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550kW (at 4ºC approach temperature difference) and 1100kW (at 8ºC approach temperature difference). Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a primary closed loop configured to circulate a first fluid;
a secondary closed loop configured to circulate a second fluid across electrical components to pick up heat from the electrical components;
a heat exchanger configured to exchange heat between the second fluid and the first fluid such that a portion of the heat picked up from the electrical components is transferred from the second fluid to the first fluid;
a first pump;
a second pump; and
a housing defining an interior compartment within which the heat exchanger, the first pump, and the second pump are housed, wherein the housing includes a frame having a top side, a bottom side positioned opposite the top side, and a plurality of corner segments extending between the top side and the bottom side,
wherein the bottom side includes a plurality of casters configured to support a weight of the cooling distribution unit, and wherein the bottom side further includes a plurality of leveling feet.

2. The cooling distribution unit of claim 1, wherein the plurality of leveling feet are configured to support the weight of the cooling distribution unit in place of the plurality of casters.

3. The cooling distribution unit of claim 1, wherein the top side includes a plurality of eyelet hooks.

4. The cooling distribution unit of claim 1, wherein the first pump and the second pump are redundant pumps.

5. The cooling distribution unit of claim 4, wherein the first pump and the second pump are identical pumps.

6. The cooling distribution unit of claim 5, wherein the second pump is be configured to automatically turn on in response to failure of the first pump.

7. The cooling distribution unit of claim 1, wherein the first pump is arranged on a first slide plate and the second pump is arranged on a second slide plate.

8. The cooling distribution unit of claim 7, wherein the first slide plate and the second slide plate are arranged within the interior compartment and are attached to an interior portion of the bottom side.

9. The cooling distribution unit of claim 1, wherein the plurality of casters are positioned at the plurality of corner segments.

10. The cooling distribution unit of claim 9, wherein one of the plurality of casters rotates about a vertical axis, and wherein the vertical axis extends through one of the plurality of corner segments.

11. The cooling distribution unit of claim 1, wherein one of the plurality of leveling feet is positioned adjacent one of the plurality of casters.

12. The cooling distribution unit of claim 1, wherein one of the plurality of leveling feet includes a screw portion and a plate, wherein the plate is configured to rotate about the screw portion.

13. The cooling distribution unit of claim 12, wherein the plate includes a threaded aperture configured to receive the screw portion.

14. The cooling distribution unit of claim 13, wherein when the plate is rotated in a clockwise direction, the plate is configured to move up the screw portion, thereby shortening the one of the plurality of leveling feet.

15. A cooling distribution unit comprising:
a primary closed loop configured to circulate a first fluid;
a secondary closed loop configured to circulate a second fluid across electrical components to pick up heat from the electrical components;
a heat exchanger configured to exchange heat between the second fluid and the first fluid such that a portion of the heat picked up from the electrical components is transferred from the second fluid to the first fluid;
a first pump;
a second pump; and
a housing defining an interior compartment within which the heat exchanger, the first pump, and the second pump are housed;
wherein the first pump is arranged on a first slide plate and the second pump is arranged on a second slide plate.

16. The cooling distribution unit of claim 15, wherein the first slide plate is arranged on a first rail within the interior compartment.

17. The cooling distribution unit of claim 16, wherein the first slide plate is configured to slide along the first rail along a lateral direction.

18. The cooling distribution unit of claim 17, wherein the second slide plate is arranged on a second rail within the interior compartment of the housing.

19. The cooling distribution unit of claim 18, wherein the second slide plate is configured to slide along the second rail along the lateral direction.

20. The cooling distribution unit of claim 15, further comprising a caster coupled to the housing.
